(19) United States
(12) Patent Application Publication
(10) Pub. No.: US 2013/0070419 A1
(43) Pub. Date: Mar. 21, 2013

(54) ELECTRONIC DEVICE WITH HEAT DISSIPATING MODULE

(71) Applicants: CHIH-HAO YANG, Tu-Cheng (TW); XIANG-KUN ZENG, Shenzhen City (CN); CHENG HAO, Shenzhen City (CN); ER-WEI LU, Shenzhen City (CN)

(72) Inventors: CHIH-HAO YANG, Tu-Cheng (TW); XIANG-KUN ZENG, Shenzhen City (CN); CHENG HAO, Shenzhen City (CN); ER-WEI LU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/483,305

(22) Filed: May 30, 2012

(30) Foreign Application Priority Data
Sep. 21, 2011 (CN) 201110281681.X

(51) Int. Cl. H05K 7/20

(52) U.S. Cl. 361/700; 361/688

(57) ABSTRACT

An electronic device includes a circuit board and a heat dissipating module. The circuit board includes a body and a first heat generating part located on the body. The body defines a through hole close to the first heat generating part. The heat dissipating module includes a heat pipe, a first heat dissipating piece attached to the heat pipe and a resilient piece. The resilient piece includes a securing portion secured to the first heat dissipating piece and a resilient arm. The resilient arm is engaged in the through hole to secure the first heat dissipating piece to the body. The first heat dissipating piece abuts the first heat generating part, and the resilient arm is elastically deformable to disengage from the through hole.

### BACKGROUND

1. Technical Field

The present disclosure relates to electronic devices, and particularly to an electronic device with a heat dissipating module.

2. Description of Related Art

Circuit boards, such as a motherboard, are located on an enclosure of a server or a computer. A plurality of heat generating parts may be located on the circuit board. A typical heat dissipating module is installed on the circuit board for dissipating heat generated by the heat generating parts. The heat dissipating module may include a heat dissipating device, a heat pipe located on the heat dissipating device, and a plurality of heating pieces attached to the heat pipe. Each of the heat dissipating modules abuts each of the heat generating parts and is secured to the corresponding heat generating parts by a plurality of screws. However, assembly or disassembly of the heat dissipating pieces is very time-consuming and inconvenient.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an electronic device, the electronic device comprising a circuit board and a heat dissipating module.

FIG. 2 is an enlarged view of a circled portion II of FIG. 1.

FIG. 3 is an assembled view of the circuit board and the heat dissipating module of FIG. 1 shown in one state.

FIG. 4 is a cross-sectional view of the electronic device of FIG. 3, taken along the line IV-IV.

FIG. 5 is another assembled view of the circuit board and the heat dissipating module of FIG. 1 shown in another state.

FIG. 6 is a cross-sectional view of the electronic device of FIG. 5, taken along the line VI-VI.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

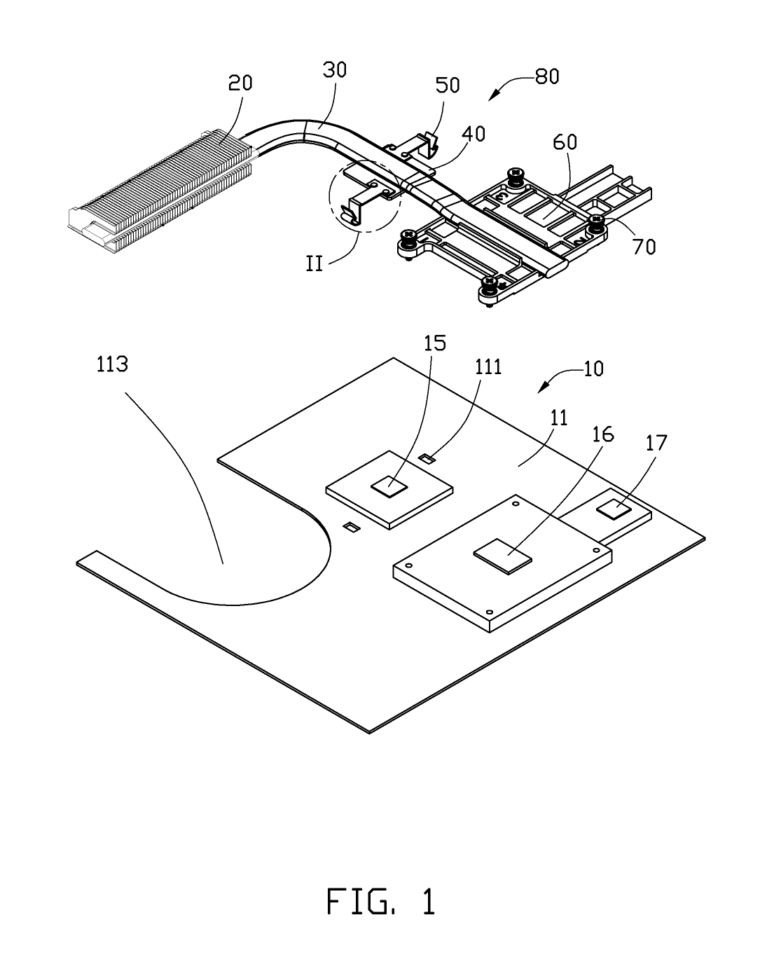

Referring to FIG. 1, an electronic device of one embodiment includes a circuit board 10 and a heat dissipating module 80. In one embodiment, the circuit board 10 is a mother board of a server or a computer.

The circuit board 10 includes a body 11. A first heat generating part 15, a second heat generating part 16, and a third heat generating part 17 are located on the body 11. The body 11 defines two through holes 111 at two opposite sides of the first heat generating part 15. The body 11 defines a cutout 113 in one side of the first heat generating part 15. In one embodiment, the cutout 113 is substantially U-shaped.

The heat dissipating module 80 includes a heat dissipating device 20, a heat pipe 30, a first heat dissipating piece 40, two resilient pieces 50, and a second heat dissipating piece 60. In one embodiment, the heat pipe 30 is substantially L-shaped.

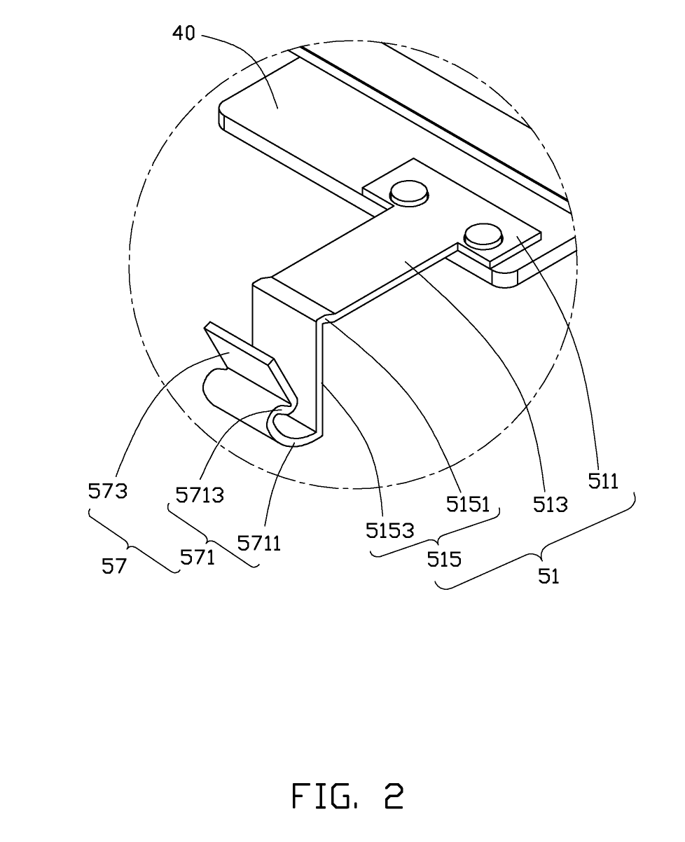

Referring to FIG. 2, each of the resilient pieces 50 includes a securing portion 51 and a resilient arm 57. The securing portion 51 includes a fixing portion 511, a first resilient portion 513, and a connecting portion 515. The first resilient portion 513 extends horizontally from the fixing portions 511. In one embodiment, the first resilient portion 513 and the fixing portion 511 are in the same plane, and the first resilient portion 513 is substantially parallel to the first heat dissipating piece 40. The connecting portion 515 includes a linking portion 5151 and a stretching portion 5153. The linking portion 5151 extends from a free distal end of the first resilient portion 513. In one embodiment, an obtuse angle is defined between the linking portion 5151 and the first resilient portion 513. The stretching portion 5153 extends downwards from a free distal end of the linking portion 5151. In one embodiment, a first acute angle is defined between the linking portion 5151 and the stretching portion 5153. The stretching portion 5153 is substantially perpendicular to the first resilient portion 513.

The resilient arm 57 includes a latch portion 571 and an operating portion 573 extending from the latch portion 571. In one embodiment, a cross-section of the resilient arm 57 is substantially S-shaped. The latch portion 571 includes a second resilient portion 5711 and a resisting portion 5713. The second resilient portion 5711 extends from a free distal end of the stretching portion 5153. The resisting portion 5713 is bent backwards from a distal end of the second resilient portion 5711. In one embodiment, the resisting portion 5713 is substantially arc-shaped. The operating portion 573 extends from a distal end of the resisting portion 5713 to tilt away the stretching portion 5153. In one embodiment, a first plane contains the operating portion 5713, and a second acute angle is defined between the first plane and stretching portion 5153.

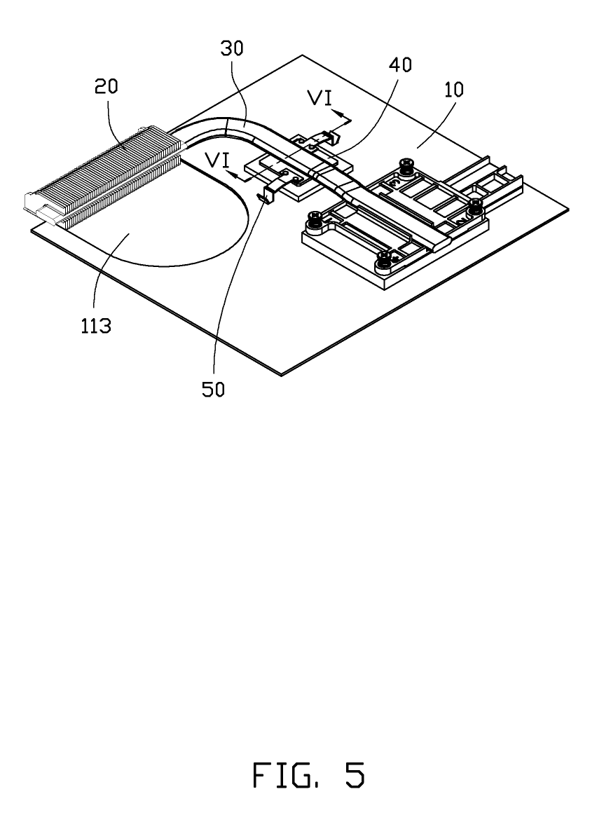

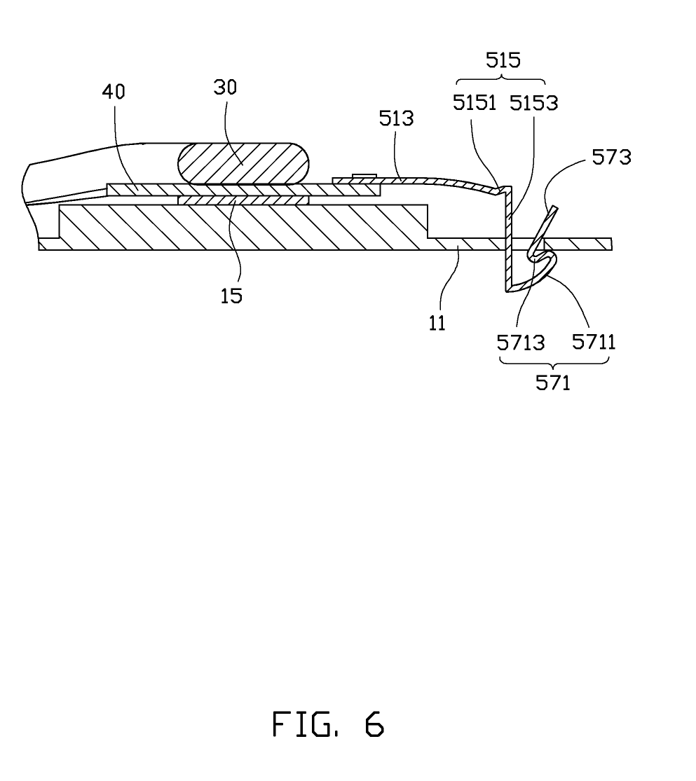

Referring to FIGS. 5 and 6, in assembly, the two resilient pieces 50 are separately secured to two opposite sides of the first dissipating piece 40. The two resilient pieces 50 can be symmetrical or asymmetrical about the first dissipating piece 40. The first heat dissipating piece 40 is attached below the heat pipe 30. The heat pipe 30 is located between the two resilient pieces 50. The heat dissipating device 20 communicates with a first end of the heat pipe 30, and the second heat dissipating piece 60 is secured to the heat pipe 30 below a second end of the heat pipe 30. The heat dissipating device 20 and the second heat dissipating piece 30 can be welded to the heat pipe 30.

In assembling the dissipating module 80 to the circuit board 10, the heat dissipating device 20 is received in the cutout 113. The second heat dissipating piece 60 can be secured to the circuit board 10 by a plurality of fixing members 70, such as fasteners, and abuts the second heat generating part 16 and the third heat generating part 17. The first heat dissipating piece 40 is placed on the first heat generating part 15. The second resilient portion 5711 of each resilient piece 50 can elastically bend to towards the stretching portion 5153 by biasing the operating portion 573. The first resilient portion 513 elastically bends to move the resilient arm 57 towards the body 11 of the circuit board 10, until the latch portion 571 extends through the through hole 111. The second resilient portion 5711 elastically returns with the resisting portion 5713 engaging with the body 11, and the operating portion 573 abutting an edge of the through hole 111. Thus, the first heat dissipating piece 40 closely abuts the first heat generating part 15 to dissipate heat generated by the first heat generating part 15.

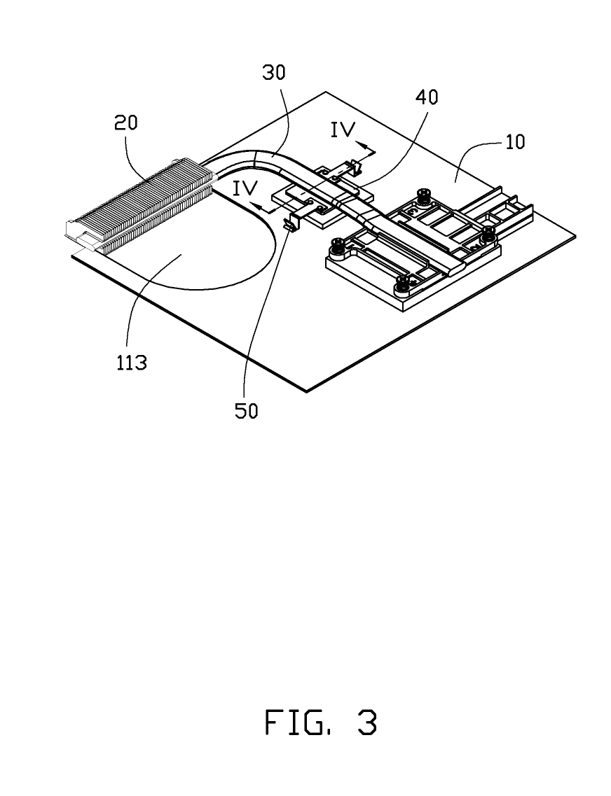

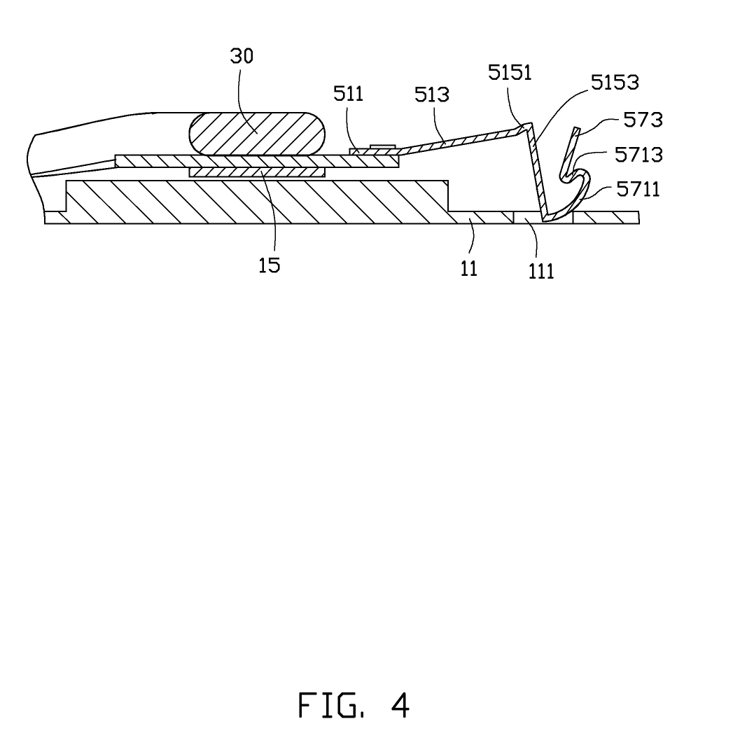

Referring to FIGS. 3 and 4, in disassembly, the second resilient portion 5711 of each resilient piece 50 can elastically bend towards the stretching portion 5153 by biasing the operating portion 573 to disengage the latch portion 57 from the through hole 111. Thus, the first heat dissipating piece 40 is easily detached from the circuit board 10.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device comprising:
a circuit board comprising a body, a first heat generating part located on the body, and a through hole defined in the body adjacent to the first heat generating part;
a heat dissipating module comprising a heat pipe, a first heat dissipating piece, and a resilient piece, wherein the first heat dissipating piece attached to the heat pipe; the resilient piece comprises a securing portion and a resilient arm; the securing portion is secured to the first heat dissipating piece, and the resilient arm is connected to the securing portion; the resilient arm is engaged in the through hole to secure and abut the first heat dissipating piece to the first heat generating part, and the resilient arm is elastically bent to disengage from the through hole.

2. The electronic device of claim 1, wherein the securing portion comprises a fixing portion and a first resilient portion extending from the fixing portion, the fixing portion is secured to the first heat dissipating piece, and the first resilient portion is substantially parallel to the first heat dissipating piece.

3. The electronic device of claim 2, wherein the first resilient portion is elastically bent to the first heat dissipating piece closely abut the first heat generating part.

4. The electronic device of claim 2, wherein the securing portion further comprises a linking portion extending from a distal end of the first resilient portion, and an obtuse angle is defined between the first resilient portion and the linking portion.

5. The electronic device of claim 4, wherein the securing portion comprises a stretching portion extending from a distal end of the linking portion, and a first acute angle is defined between the linking portion and the stretching portion.

6. The electronic device of claim 5, wherein the stretching portion is substantially perpendicular to the first resilient portion.

7. The electronic device of claim 5, wherein the resilient arm comprises a latch portion connected to the stretching portion, and the latch portion extends through the through hole to engage with the body.

8. The electronic device of claim 7, wherein the latch portion comprises a second resilient portion extending from the stretching portion and a resisting portion bent from the second resilient portion; the second resilient portion is elastically bent to disengage the resisting portion from the through hole.

9. The electronic device of claim 8, wherein the resilient arm further comprises an operating portion extending from the resisting portion, and a second acute angle is defined between the operating portion and the stretching portion.

10. The electronic device of claim 9, wherein the operating portion is received in the through hole and abuts an edge of the through hole.

11. An electronic device comprising:
a circuit board comprising a body, a first heat generating part located on the body, and a through hole defined in the body adjacent to the first heat generating part;
a heat dissipating module comprising a first heat dissipating piece and a resilient piece secured to the first heat dissipating piece, wherein the resilient piece is engaged in the through hole to secure and abut the first heat dissipating piece to the first heat generating part, and the resilient piece is elastically bent to disengage from the through hole.

12. The electronic device of claim 11, wherein the resilient piece comprises a securing portion and a resilient arm connected to the securing portion, the securing portion is secured to the first heat dissipating piece, and the resilient arm is engaged in the through hole.

13. The electronic device of claim 12, wherein the securing portion comprises a fixing portion and a first resilient portion extending from the fixing portion, the fixing portion is secured to the first heat dissipating piece, and the first resilient portion is elastically bent to the first heat dissipating piece closely abut the first heat generating part.

14. The electronic device of claim 13, wherein the securing portion further comprises a linking portion extending from a distal end of the first resilient portion, and an obtuse angle is defined between the first resilient portion and the linking portion.

15. The electronic device of claim 14, wherein the securing portion comprises a stretching portion extending from a distal end of the linking portion, and a first acute angle is defined between the linking portion and the stretching portion.

16. The electronic device of claim 15, wherein the stretching portion is substantially perpendicular to the first resilient portion.

17. The electronic device of claim 12, wherein the resilient arm comprise a latch portion connected to the securing portion, and the latch portion extends through the through hole to engage with the body.

18. The electronic device of claim 17, wherein the latch portion comprises a second resilient portion extending from the securing portion and a resisting portion bent from the second resilient portion; the second resilient portion is elastically bent to the disengage the resisting portion from the through hole.

19. The electronic device of claim 18, wherein the resilient arm further comprises an operating portion extending from the resisting portion, and a second acute angel is defined between the operating portion and the securing portion.

20. The electronic device of claim 19, wherein the operating portion is received in the through hole and abuts edge of the through hole.
